(19) United States
(12) Patent Application Publication
(10) Pub. No.: US 2024/0280911 A1
(43) Pub. Date: Aug. 22, 2024

(54) DIGITAL LITHOGRAPHY EXPOSURE UNIT BOUNDARY SMOOTHING

(71) Applicant: Applied Materials, Inc., Santa Clara, CA (US)

(72) Inventors: CHI-MING TSAI, San Jose, CA (US); THOMAS L. LAIDIG, Richmond, CA (US); DOUGLAS VAN DEN BROEKE, Sunnyvale, CA (US)

(21) Appl. No.: 18/568,993

(22) PCT Filed: Jun. 14, 2021
(86) PCT No.: PCT/US21/37283

§ 371 Date: Dec. 11, 2023

(51) Int. Cl. G03F 7/00

(52) U.S. Cl. CPC G03F 7/70475; G03F 7/70275; G03F 7/70358; G03F 7/70558; G03F 7/70833

(57) ABSTRACT

A digital lithography system includes scan regions including a first scan region and a second scan region adjacent to the first scan region. The digital lithography system further includes exposure units located above the scan regions, a memory, and at least one processing device operatively coupled to the memory. The exposure units include a first exposure unit associated with the first scan region and a second exposure unit associated with the second scan region. The processing device is to perform operations including initiating a digital lithography process to pattern a substrate disposed on the stage in accordance with instructions, and performing exposure unit boundary smoothing with respect to the first and second exposure units during the digital lithography process.

### TECHNICAL FIELD

The instant specification generally relates to electronic device fabrication. More specifically, the instant specification relates to digital lithography.

### BACKGROUND

Photolithography is used in the manufacturing of semiconductor devices and display devices, such as flat panel display devices. Examples of flat panel display devices include thin-film display devices, such as, e.g., liquid crystal display (LCD) devices and organic light emitting diode (OLED) display devices. Large-area substrates can be used to manufacture flat panel display devices for use with computers, touch panel devices, personal digital assistants (PDAs), cell phones, television monitors, etc.

In digital lithography, multiple exposure units are used to increase throughput, where each exposure unit is responsible for a portion of a printing area. However, different exposure units typically have slight variations in their characteristics. This can result in visible boundaries between regions printed by the different exposure units. For display devices, the visible boundaries are defects that can cause manufactured displays to be scrapped.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with an embodiment, a digital lithography system is provided. The digital lithography system includes scan regions including a first scan region and a second scan region adjacent to the first scan region. The digital lithography system further includes exposure units located above the scan regions, a memory, and at least one processing device operatively coupled to the memory. The exposure units include a first exposure unit associated with the first scan region and a second exposure unit associated with the second scan region. The processing device is to perform operations including initiating a digital lithography process to pattern a substrate disposed on the stage in accordance with instructions, and performing exposure unit boundary smoothing with respect to the first and second exposure units during the digital lithography process.

In accordance with another embodiment, a system is provided. The system includes a memory and at least one processing device, operatively coupled to the memory, to perform operations including initiating a digital lithography process to pattern a substrate in accordance with instructions, and performing exposure unit boundary smoothing with respect to a first exposure unit of a plurality of exposure units and a second exposure unit of the plurality of exposure units during the digital lithography process. The first exposure unit corresponds to a first scan region and the second exposure unit corresponds to a second scan region adjacent to the first scan region.

In accordance with yet another embodiment, a method is provided. The method includes initiating, by a processing device, a digital lithography process to pattern a substrate in accordance with instructions, and performing, by the processing device, exposure unit boundary smoothing with respect to a first exposure unit of a plurality of exposure units and a second exposure unit of the plurality of exposure units during the digital lithography process. The first exposure unit corresponds to a first scan region and the second exposure unit corresponds to a second scan region adjacent to the first scan region.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a top-down view of a digital lithography system, in accordance with some embodiments

FIGS. 2A-2D are top-down views showing a scan path of a substrate through a single digital lithography exposure unit of a digital lithography system, in accordance with some embodiments.

FIGS. 3A-3C are diagrams showing examples of digital lithography exposure unit boundary smoothing, in accordance with some embodiments.

FIG. 4 is a diagram of example scan configurations of digital lithography exposure units in a one-bridge implementation, in accordance with some embodiments.

FIG. 5 is a diagram of example scan configurations of digital lithography exposure units in a two-bridge implementation, in accordance with some embodiments.

FIG. 6 is a diagram of an example of dose allocations of digital lithography exposure units in a one-bridge implementation, in accordance with some embodiments;

FIG. 7 is a diagram illustrating an example of dose allocations of digital lithography exposure units in a two-bridge implementation, in accordance with some embodiments;

FIGS. 8A-8C are diagrams showing examples of digital lithography exposure unit dose allocations, in accordance with some embodiments.

FIG. 9 is a flow chart of a method for implementing digital lithography exposure unit boundary smoothing, in accordance with some embodiments.

FIG. 10 is a block diagram of a digital lithography system, in accordance with some embodiments.

FIG. 11 is a block diagram illustrating a computer system, according to certain embodiments.

### DETAILED DESCRIPTION

Digital lithography can be used to generate a pattern (e.g., for a digitally aligned etch mask) onto a substrate surface without the use of a photomask (e.g., via maskless lithography). Digital lithography technology (e.g., such as Texas Instruments'® programmable light steering technology) enables high speed and high-resolution maskless lithography solutions for printed circuit board (PCB) patterning, solder masks, flat panel displays, laser marking, and other digital exposure systems that benefit from high speed and precision. Digital lithography is used to directly expose patterns onto photoresist films without the use of contact masks (e.g., photomasks). This can reduce material cost, improves production rates, and allow for rapid changes of the pattern. Direct exposure increases productivity compared to narrow laser beam or masked systems. An advantage of digital lithography is the ability to change lithography patterns from one run to the next, without incurring the cost of generating a new photomask. Illustratively, digital lithography can be used to perform large-area patterning during electronic device fabrication.

In digital lithography, multiple digital lithography exposure units (“exposure units”) can be used to improve throughput of a digital lithography tool. Conventional exposure units can print or expose a rectangular non-overlapping region, or clipping layer. The clipping layer may serve as a filter to inform layout-processing software to keep patterns to be printed by a particular exposure unit on the clipping layer associated with that exposure unit. Each of the multiple exposure units can be responsible for a portion of the printing area and for a different clipping layer. Different exposure units can have unique characteristics that do not match exactly. This mismatch can result in non-uniformity (e.g., unevenness, inconsistency, irregularity) at exposure unit boundaries. This non-uniformity can reduce yield and thus decrease value.

Aspects and implementations of the present disclosure address these and other shortcomings of existing technologies by performing exposure unit boundary smoothing with respect to at least one pair of digital lithography exposure units (“exposure units”). The exposure unit boundary smoothing can blend the exposure unit boundaries to reduce non-uniformity and to eliminate linear boundaries between clipping layers of adjacent exposure units. The blending can result in a gradual transition between the pair of exposure units. A number of methods can be utilized to performing exposure unit boundary smoothing in accordance with the implementations described herein. The exposure unit boundary smoothing can be performed for a one-bridge case (e.g., to smooth the boundary between adjacent scan regions corresponding to exposure units attached to a same bridge), a two-bridge case (e.g., to smooth the boundary between adjacent scan regions corresponding to exposure units attached to different bridges), etc.

In some embodiments, performing exposure unit boundary smoothing includes performing exposure unit boundary shifting. More specifically, during exposure unit boundary shifting, an exposure unit boundary can be shifted for each pass. Shifting the exposure unit boundary for each pass can work particularly well for multi-pass printing.

In some embodiments, performing exposure unit boundary smoothing includes performing dose mixing. For example, dose mixing can include performing staircase blending. As another example, dose mixing can include gradual blending, Dose mixing can provide improved tradeoff between blending and Takt time (i.e., the amount of time between the start of production of a first unit and the start of production of a second unit).

Aspects and implementations of the present disclosure result in technological advantages over other approaches. For example, as mentioned above, non-uniformity at the boundary of a pair of adjacent exposure units and/or non-uniformity at the boundary of a pair of scans associated with a given exposure unit can be reduced. Accordingly, improved photolithography for patterning substrates can be achieved.

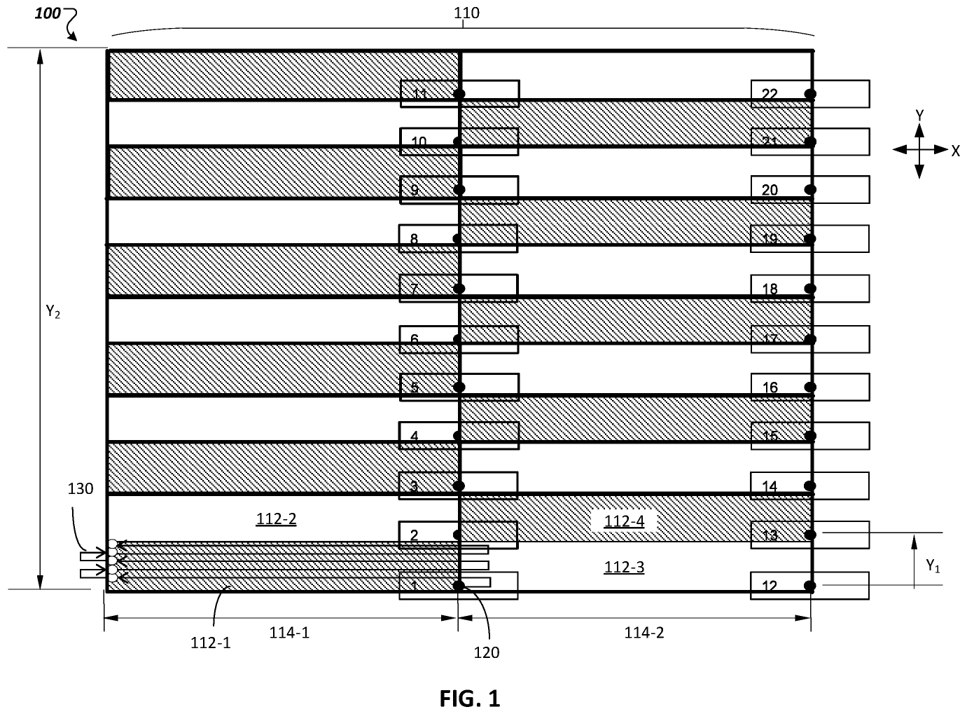

FIG. 1 is a top-down view of a digital lithography system (“system”) 100, in accordance with some embodiments. As shown, the apparatus 100 includes a stage assembly 110 including a base (e.g., a granite base), a stage and a substrate disposed on the stage. The substrate may be a glass plate, a wafer, a PCB, or other type of substrate. The substrate may correspond to or be positioned in a digital lithography printing or scanning area having a number of scan regions, including scan regions 112-1 through 112-4. The left portion of the stage assembly 110 corresponds to a first bridge 114-1 above the stage assembly 110 and the right portion of the stage assembly 110 corresponds to a second bridge 114-2 above the stage assembly 110. As will be described in further detail below, exposure units are attached to the bridges 114-1 and 114-2. In some embodiments, the length of each bridge 114-1 and 114-2 can range between about 500 (millimeters) mm and about 1000 mm. For example, the length of each bridge 114-1 and 114-2 can be about 750 mm.

The substrate can include a photoresist material disposed on a material to be etched. The photoresist material can be a positive photoresist material (i.e., where a portion of the photoresist material that is exposed to light becomes soluble to a photoresist developer) or a negative photoresist material (i.e., where a portion of the photoresist material that is exposed to light becomes insoluble to a photoresist developer). Thus, by removing designated portions of the photoresist material, a photoresist pattern can be formed. In some embodiments, the material to be etched is a conductive material (e.g., metal). For example, the conductive material can be molybdenum. After the designated regions of the photoresist material are removed, the now-exposed material can be etched in accordance with the photoresist pattern. For example, wiring can be formed during the etch process. Alternatively, the patterned material can itself be photosensitive, eliminating the need to add a photoresist layer and performing the following etch process.

To perform the photoresist patterning, the apparatus 100 further includes a first column of digital lithography exposure units (“exposure units”) hanging from the first bridge 114-1 and a second column of exposure units hanging from the second bridge 114-2. For example, the first column of exposure units includes exposure units 1 through 11 and the second column of exposure units includes exposure units 12 through 22. Thus, in this illustrative example, there are 22 total exposure units shown. However, the number of exposure units shown in FIG. 1 should not be considered limiting, and the system 100 can include any suitable number of exposure units accordance with the embodiments described herein.

Each exposure unit can include a lens assembly that can project an image onto the photoresist material of the substrate. Each lens assembly is shown adjacent to a bottom-right corner of its associated scan region. For example, a lens assembly 120 of exposure unit 1 is associated with the scan region 112-1. In some embodiments, each lens assembly is about 4 mm tall and about 3 mm wide. However, each lens assembly can have any suitable dimensions in accordance with the embodiments described herein.

During a digital lithography process, each exposure unit is moved relative to the substrate to expose a region (e.g., a rectangular region) of the substrate to electromagnetic radiation such as light (e.g., ultraviolet light, near-ultraviolet light, etc.). During scanning, the exposure units expose respective scan regions, in accordance with a programmed scan path. Instead of having the exposure units move above the stage assembly 110, the stage assembly 110 can move in the X-Y direction underneath the exposure units in accordance with the programmed scan path. Since the field-of-view of a lens assembly (e.g., lens assembly 120) can be smaller than its associated scan region (e.g., scan region 112-1), the stage assembly 110 may have to move back and forth repeatedly until the entire scan region (e.g., scan region 112-1) is printed. The lens assembly 120 is projected to scan the scan region 112-1, except for the first and last scans where trimming may occur based on the definition of the scan region 112-1. The greater the number of exposure units, the fewer scans that may be performed, which can correspond to higher throughput.

Each exposure unit can be responsible for a different scan region, which may or may not overlap with the adjacent scan regions of other exposure units. To avoid abrupt transitions from a first scan region to a second scan region adjacent to the first scan region (either attached to the same bridge or to a different bridge), the exposure unit corresponding to the first scan region can encroach into the second scan region. Similarly, the exposure unit corresponding to the second scan region can encroach into the first scan region. For example, exposure unit 1 can encroach into scan region 112-2 and/or scan region 112-3, and exposure unit 2 can encroach into scan region 112-1 and/or scan region 112-4. Accordingly, shared exposures can be observed at boundaries or “stitching lines” between adjacent exposure units of the same bridge and/or exposure units on different bridges.

A stitching line can be defined by a clipping layer, which can be a software-defined layer that sets the scan path boundary for each exposure unit during movement of the stage assembly 110. A stitching line may be visible on the substrate after printing due to non-ideal printing conditions. For example, if the actual location of an exposure unit is shifted by about 1 micron, there may be a 1 micron-wide gap or double exposed band near the stitching line. Although the stitching lines in this illustrative example are shown as straight lines (such that the scan regions are rectangular shaped), the stitching lines can be curvy (e.g., wavy).

For example, a path 130 of the exposure unit 120-1 is illustratively depicted. The path 130 proceeds in a snake-like fashion. More specifically, during scanning, the stage assembly 110 moves in the X direction (i.e., from right to left) across the scan region 120-1, during which time the exposure unit 120-1 patterns a line across the scan region 120-1. The stage assembly 110, upon reaching the left edge of the scan region 112-1, moves in the Y-direction (i.e., up), and then moves in the X-direction (i.e., from left to right) to pattern another line across the scan region 120-1. The path 130 proceeds in this snake-like fashion until reaching the opposite end of the scan region 120-1, at which point a full image has been patterned on the substrate. The image can then be developed for substrate etching. The distance of stage travel in the Y-direction during scanning, “Y₁”, can be any suitable distance in accordance with the embodiments described herein. In some embodiments, Y₁ can range between about 150 mm and about 180 mm. For example, Y₁ can be about 164 mm. The scan distance in the X direction for each exposure unit corresponds to the length of the bridges 114-1 and 114-2 in embodiments. The total width of the scan regions, “Y₂”, can be any suitable width in accordance with the embodiments described herein. In some embodiments, “Y₂” can range between about 1600 mm and about 2000 mm. For example, Y₂ can be about 1800 mm. The travel distance for each scan (e.g., in the X-direction) can be different due to differences in substrate size. For example, in some embodiments, the substrate includes an 8-inch round wafer. As another example, in some embodiments, the substrate includes a 12-inch round wafer.

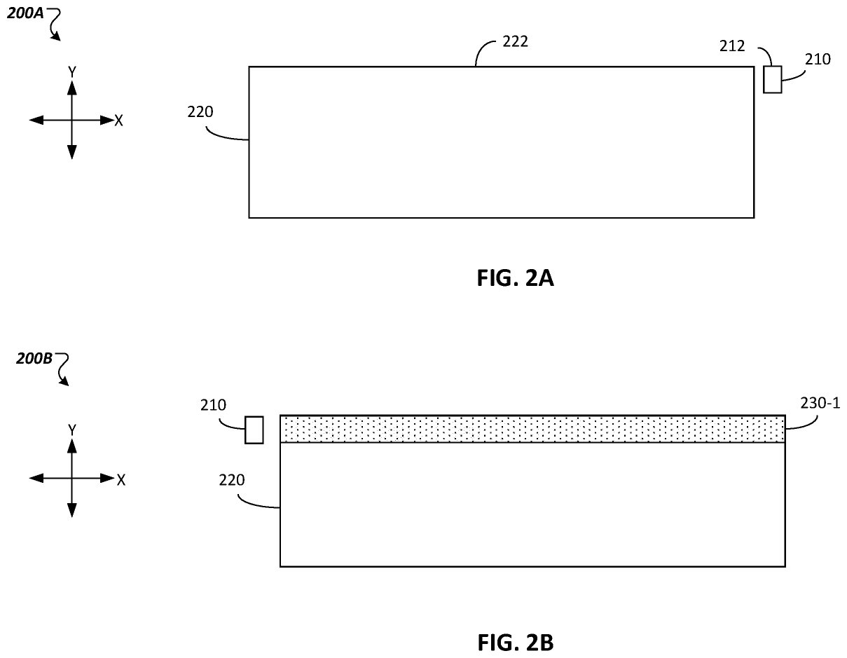

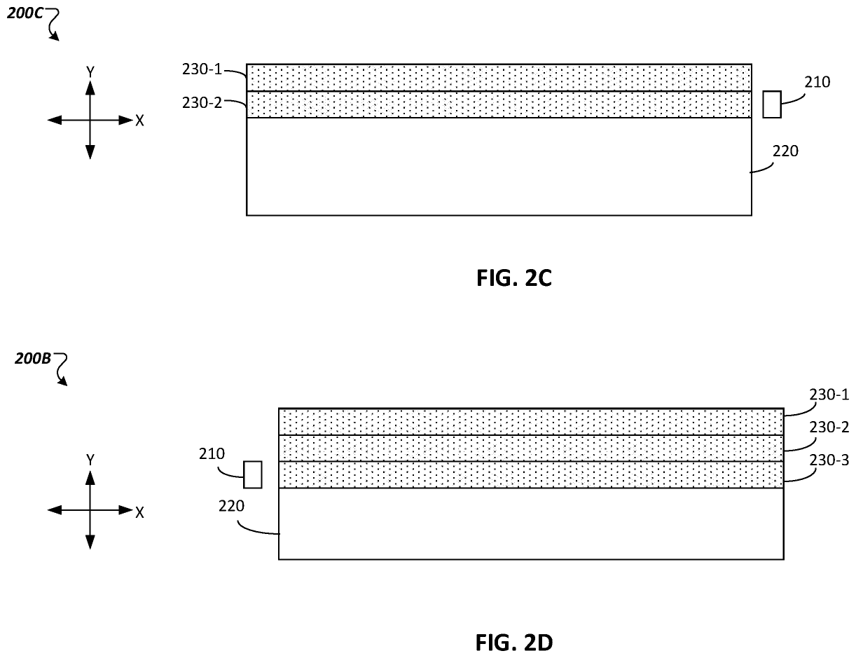

The scanning process shown in FIG. 1 can be used to create a display (e.g., a flat panel display) in embodiments. In some embodiments, the display is a liquid-crystal display (LCD). Further details regarding the scan path 130 the exposure unit 120-1 will now be described below with reference to FIGS. 2A-2D.

FIGS. 2A-2D are top-down views 200A-200B of a scan path of a substrate 220 through a single digital lithography exposure unit (“exposure unit”) 210 of a digital lithography system, in accordance with some embodiments. The exposure unit 210 can be, for example, the exposure unit 120-1 of the digital lithography system 100 described above with reference to FIG. 1. The substrate 220 is disposed on a stage (not shown).

FIG. 2A shows the exposure unit 210 and a scan region 220 of a substrate prior to a first scan being performed using the exposure unit 210. An edge 222 of the scan region 220 can be aligned with an edge 212 of the exposure unit 210 prior to a first scan performed. The stage moves the substrate in the X-Y direction(s) in accordance with a digital lithography scanning procedure performing a number of scans across the scan region 220.

FIG. 2B shows the formation of a scanned area 230-1 within the scan region 220 after the first scan is performed using the exposure unit 210. More specifically, the stage moves the substrate in the positive X direction underneath the exposure unit 210 to form the scanned area 230-1.

FIG. 2C shows the formation of a scanned area 230-2 after a second scan is performed using the exposure unit 210. More specifically, after the first scan is performed using the exposure unit 210, the stage moves the substrate in the positive Y direction to align the exposure unit 210 with the next designated region, and then the stage moves the substrate in the negative X direction underneath the exposure unit 210 to form the scanned area 230-2.

FIG. 2D shows the formation of a scanned area 230-2 after a second scan is performed using the exposure unit 210. More specifically, after the second scan is performed using the exposure unit 210, the stage moves the substrate in the positive Y direction to align the exposure unit 210 with the next designated region, and then the stage moves the substrate 220 in the positive X direction underneath the exposure unit 210 to form the scanned area 230-3. Additional scans can be performed to finish the scanning.

During the scanning process described above, one or more “mura” problems can be observed. Mura is a Japanese term that generally refers to any visible variation that occurs across the display that occurs due to the scanning process.

One example of mura is “scan mura” that occurs after every scan. For example, one type of scan mura is illumination non-uniformity, in which the exposure field of an exposure unit is inconsistent (e.g., a top edge of the exposure field has a different illumination field than a bottom edge). More specifically, every time a scan is performed to scan a line or “paint a stripe,” the top edge of the scan will be brighter or dimmer than the bottom edge. This can adversely affect the patterning dimensions. Another example of mura is “vibrational mura,” where vibrations resulting from operation of the digital lithography system can cause exposure units to vibrate, resulting in scan choppiness. Since the exposure unit vibrations may not be spatially synchronized, this can result in visible variations across the display.

Another example of mura is “boundary mura,” in which an abrupt change in appearance can be observed at the boundary or edge of a region scanned by one exposure unit and an adjacent region scanned by another exposure unit. For example, boundary mura can occur at the boundary between regions scanned by a pair of adjacent exposure units of a given bridge (e.g., the boundary between scan regions 112-2 and 112-4 of FIG. 1). As another example, boundary mura can occur at the boundary between regions scanned by a pair of adjacent exposure units corresponding to different bridges (e.g., the boundary between scan regions 112-1 and 112-2 of FIG. 1).

There can be a variety of different microscopic and/or macroscopic causes of boundary mura. For example, if one exposure unit is outputting more light than an adjacent exposure unit during scanning, then a sudden change in the line widths of the printed lines can be observed across the boundary between the exposure units. As another example, if one exposure unit is out of focus compared to the other exposure unit, then a photoresist sidewall profile corresponding to each exposure unit can be different. For example, the exposure unit with better focus can have a more vertical sidewall, as compared to a more sloped sidewall of the exposure unit with poorer focus. Accordingly, problems can exist at the boundaries of adjacent scan regions.

As will be described in further detail herein, mura (e.g., boundary mura) can be addressed by performing exposure unit boundary smoothing to smooth the boundaries (e.g., stitching lines) between scan regions scanned by adjacent exposure units. An exposure unit boundary may correspond to an edge of a region scanned by an exposure unit. For example, exposure unit boundary smoothing can be performed to create a gradual transition between regions scanned by different exposure units (e.g., blend the boundary).

In some embodiments, performing exposure unit boundary smoothing includes performing exposure unit boundary shifting. Exposure unit boundary shifting can be performed to shift the exposure unit boundary for each pass of an exposure unit. A pass refers to a single iteration of the scan path to pattern or print lines on the substrate (conceptually similar to applying a single coat of paint). By performing multiple (i.e., two or more) passes to pattern lines on the substrate, and shifting the exposure unit boundary after each pass, the lines can be smoothed out or refined (conceptually similar to applying multiple coats of paint to smooth out paint strokes). Therefore, in embodiments, a digital lithography process may be a multi-pass digital lithography process. For the multi-pass digital lithography process, multiple passes may be performed over the same region to increase a light exposure of that region.

In some embodiments, performing exposure unit boundary smoothing includes performing dose mixing, where a dose refers to an amount of radiation or light that a region is exposed to. Dose mixing, in effect, seeks to “imitate” the results of exposure unit boundary shifting without having to perform multi-pass lithography. For dose mixing, the intensity of the light source may be adjusted during scanning of one or more portions of a region associated with an exposure unit. Alternatively, or additionally, a number of passes applied to different portions of the region associated with the exposure unit may be varied to provide different exposure levels by the exposure unit. For example, a first exposure unit may apply 100% of a target light intensity (or two passes) to achieve a full dose to a majority of a region for which the first exposure unit is responsible. However, for a portion of the region that the first exposure unit is responsible, the first exposure unit may apply 50% of the target light intensity (or a single pass at full intensity) to provide a half dose. A second exposure unit may cross over into the region for which the first exposure unit is responsible, and may apply 50% of the target light intensity (or a single pass at full intensity) to the portion of the region that received a 50% dose by the first exposure unit. Thus, the doses or exposures of two exposure units is effectively “mixed” for that portion of the region such that it receives a partial dose from one exposure unit and a partial dose from another exposure unit. As will be described in further detail herein, dose mixing can be achieved by performing a “localized multipass” at corresponding scan region boundaries. More specifically, multiple passes of a scan can be performed about the boundary to achieve a dose mixing effect. Dose mixing can provide a tradeoff between blending and Takt time as compared to exposure unit boundary shifting. In some embodiments, a combination of exposure unit boundary shifting and dose mixing is performed.

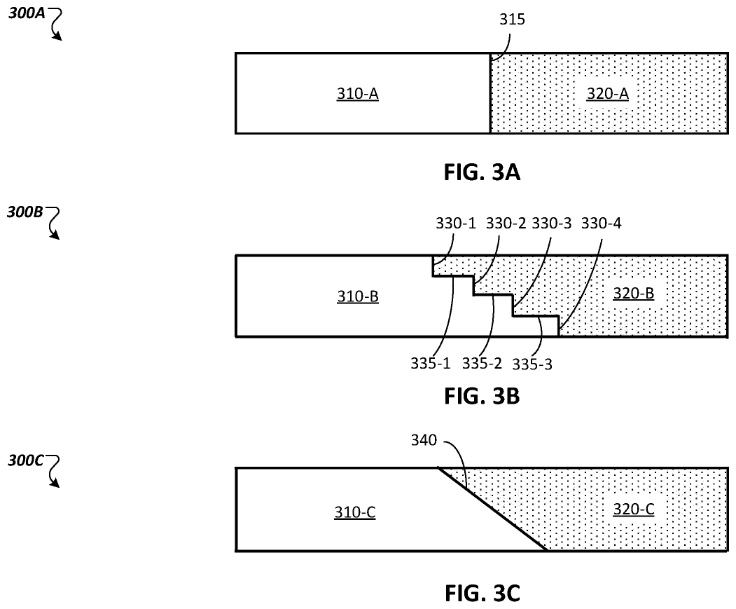

Exposure unit boundary shifting and/or dose mixing can be performed to handle boundary smoothing between adjacent scan regions with respect to exposure units attached to the same bridge (“one-bridge example”), or to handle boundary smoothing between adjacent scan regions with respect to exposure units attached to different bridges (“two-bridge example”). Further details regarding exposure unit boundary shifting and dose mixing are described below with reference to FIGS. 3-7.

FIGS. 3A-3C are diagrams 300A-300C showing examples of digital lithography exposure unit (“exposure unit”) boundary smoothing, in accordance with some embodiments. The exposure unit boundary smoothing can be achieved by performing exposure unit boundary shifting and/or dose mixing. For example, the diagrams 300A-300C can each correspond to clipping layers that define the boundaries of the exposure units.

In FIG. 3A, the diagram 300A shows a first scan region 310-A corresponding to a first exposure unit and a second scan region 320-A corresponding a second exposure unit, separated by a boundary 315. The first and second exposure units can be adjacent exposure units attached to the same bridge. For example, the first exposure unit can correspond to exposure unit 1 of FIG. 1, and the second exposure unit can correspond to exposure unit 2 of FIG. 1. Alternatively, the first and second exposure units can be adjacent exposure units attached to different bridges. For example, the first exposure unit can correspond to exposure unit 1 of FIG. 1, and the second exposure unit can correspond to exposure unit 12 of FIG. 1.

In this example, there is no exposure unit boundary smoothing between the first and second scan regions 310-A and 320-A. More specifically, the first exposure unit is 100% responsible for scanning in the first scan region 310-A up to the boundary 315, and then the second exposure unit is 100% responsible for scanning in the second scan region 320-A up to the boundary 315. In other words, the first scan region 310-A has received 100% of the dose from the first exposure unit and the second scan region 320-A received 100% of the dose from the second exposure unit.

In FIG. 3B, the diagram 300B shows a first scan region 310-B corresponding to the first exposure unit and a second scan region 320-B corresponding to the second exposure unit. Here, exposure unit boundary smoothing between the first scan region 310-B and the second scan region 320-B has resulted in a sawtooth blending. More specifically, the first exposure unit is programmed to extend into the original scan region corresponding to the second exposure unit (e.g., scan region 310-B of FIG. 3A) and the second exposure unit is programmed to extend into the original scan region corresponding to the first exposure unit (e.g., scan region 310-A of FIG. 3A). The sawtooth blending is illustrated in FIG. 3B by vertical boundaries 330-1 through 330-4 and horizontal boundaries 335-1 through 335-3. The boundaries 330-1 through 330-4 and 335-1 through 335-1 may not be visible, and are provided to illustrate the exposure unit boundary smoothing shown in FIG. 3B. A mixed dose region is defined between the vertical boundary 330-1 and the vertical boundary 330-4. With respect to the region defined by the horizontal boundary 335-1, the first exposure unit provides a 75% dose and the second exposure unit provides a 25% dose. With respect to the region defined by the horizontal boundary 335-2, both the first exposure unit and the second exposure unit provide a 50% dose. With respect to the region defined by horizontal boundary 335-3, the first exposure unit provides a 25% dose and the second exposure unit provides a 75% dose.

The boundary smoothing shown in FIG. 3B can be obtained by performing exposure unit boundary shifting and/or dose mixing. Regarding exposure unit boundary shifting, multiple passes can be performed to obtain the sawtooth blending. In this illustrative example, four passes can be performed, where the exposure unit boundary is shifted after each pass (i.e., 4-pass boundary shifting). For example, in the one-bridge case, the exposure unit boundary can be shifted vertically (e.g., by shifting the clipping layer vertically) and in the two-bridge case, the exposure unit boundary can be shifted horizontally (e.g., by shifting the clipping layer horizontally). Regarding dose mixing, while performing a single pass, a “localized multi-pass” can be performed about the original boundary 315 so as to provide for designated amount of dosing for each of the exposure units. In this illustrative example, the first and second exposure units can each provide 4 dose amounts (100%, 75%, 50% and 25%) to achieve the exposure unit boundary smoothing shown in FIG. 3B.

In FIG. 3C, the diagram 300C shows a first exposure unit region 310-C and a second exposure unit region 320-C with gradual blending corresponding to a diagonal boundary 340. Gradual blending to achieve the diagonal boundary 340 is the theoretical ideal for boundary smoothing, in that it can be obtained after a suitable number (e.g., infinite number) of passes during exposure unit boundary shifting and/or a suitably fine (e.g., infinitesimally fine) mixing of doses about the boundary for each of the exposure units during dose mixing.

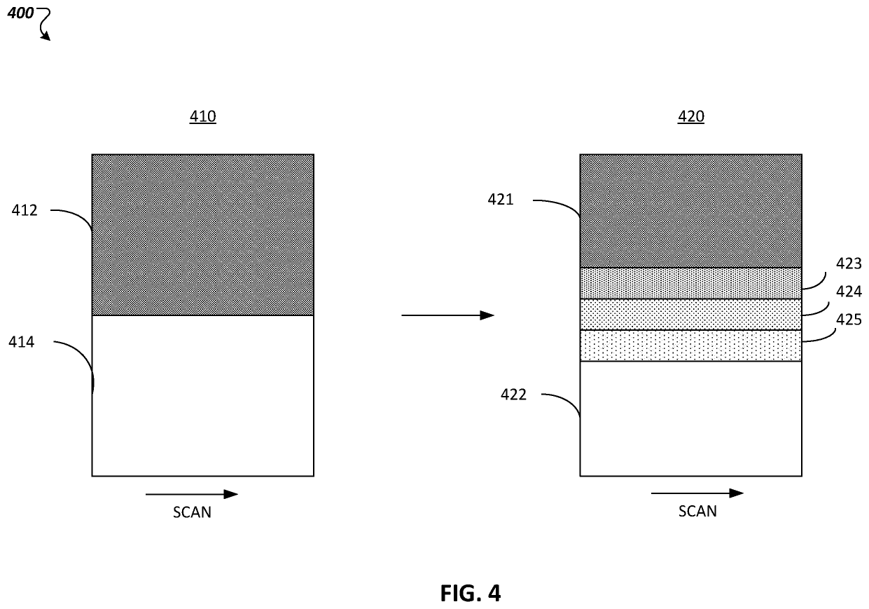

FIG. 4 is a diagram 400 of example scan configurations (“configurations”) of digital lithography exposure units (“exposure units”) in a one-bridge implementation, in accordance with some embodiments. The diagram 400 shows a first configuration 410 with no exposure unit boundary smoothing or blending. More specifically, the first configuration 410 includes a first scan region 412 corresponding to 100% dosing of a first exposure unit and a second scan region 414 corresponding to 100% dosing of a second exposure unit. For example, the scan regions 412 and 414 can be defined using clipping layers.

The diagram 400 further shows a second configuration 420 illustrating an example of exposure unit boundary smoothing or blending. More specifically, the second configuration 420 includes a first non-blended scan region 421 corresponding to 100% dosing of a first exposure unit and a second non-blended scan region 422 corresponding to 100% dosing of a second exposure unit. In addition, the second configuration 420 includes a number of blended scan regions 423-425. The blended scan region 423 can illustratively correspond to about 75% dosing of the first exposure unit and about 25% dosing of the second exposure unit. The blended scan region 424 can correspond to about 50% dosing of the first and second exposure unit regions. The blended scan region 425 can correspond to about 25% dosing of the first exposure unit and about 75% of the second exposure unit.

In some embodiments, a multi-pass exposure process can be performed to achieve the scan regions 421 through 425. More specifically, exposure unit boundary shifting can be performed by shifting the exposure unit boundary vertically after each pass (e.g., the clipping layer shifts vertically after each pass). In this illustrative example, four passes can be performed. For example, the four passes of the first exposure unit can be (1) scan region 421; (2) scan regions 421+423; (3) scan regions 421+423+424; and (4) scan regions 421+423+424+425.

The boundaries between the scan regions 421-425 are shown as being straight in the second configuration 420. However, other variations are contemplated in which the boundaries between the scan regions 421-425 are not straight. For example, the boundaries between the scan regions 421-425 can be wavy. Since the human eye is more sensitive to straight edges, non-straight boundaries can appear less obvious with respect to the same degree of mismatch between the first and second exposure units.

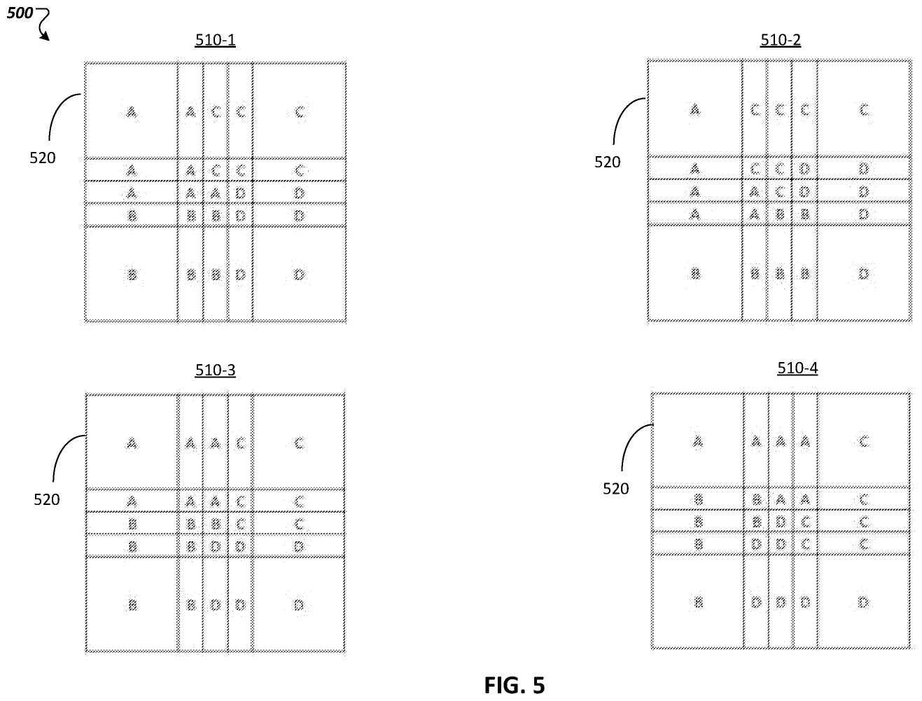

FIG. 5 shows a diagram 500 illustrating example scan configurations (“configurations”) of digital lithography exposure units (“exposure units”) in a two-bridge implementation, in accordance with some embodiments. The diagram 500 shows a number of configurations 510-1 through 510-4 corresponding respective first, second, third and fourth passes performed by exposure units A through D during a four-pass exposure process. In this example, exposure units A through D are located in adjacent scan regions, where the exposure units A and B are attached to a first bridge, and exposure units C and D are attached to a second bridge. For example, with reference to FIG. 1, exposure unit A can correspond to exposure unit 2, exposure unit B can correspond to exposure unit 1, exposure unit C can correspond to exposure unit 13, and exposure unit D can correspond to exposure unit 12.

Each of the configurations 510-1 through 510-4 is organized as a 5×5 grid of regions, including region 520, where the letters “A” through “D” written into each region signifies which exposure unit is responsible for performing the scan in the region during the corresponding pass. For example, exposure unit A is responsible for performing the scan in region 520 for each of the four passes. The configurations 510-1 through 510-4 are shown as being completely separated or disjoint for the sake of illustration. It is to be understood that boxes in corresponding locations in the grids of each configuration 510-1 through 510-4 substantially overlap during each pass. For example, region 520 in each of the configurations 510-1 through 510-4 are in substantially identical locations.

The passes shown in configurations 510-1 through 510-4 are designed to collectively satisfy a predefined blending specification. For example, the blending specification can be provided in a data structure (e.g., table). A blending specification that is satisfied by the configurations 510-1 through 510-4 is shown in the following table:

TABLE 1

| | | | | |
|---|---|---|---|---|
| 4A | 3A + C | 2A + 2C | A + 3C | 4C |
| 3A + B | 2A + B + C | 2A + 2C | A + 2C + D | 3C + D |
| 2A + 2B | 2A + 2B | A + B + C + D | 2C + 2D | 2C + 2D |
| A + 3B | A + 2B + D | 2B + 2D | B + C + 2D | C + 3D |
| 4B | 3B + D | 2B + 2D | B + 3D | 4D |

Table 1 is organized as a 5×5 table, where each box defines a total number of scans to be performed by one or more of the exposure units A-D in a corresponding region at the end of the four-pass process. For example, the entry “4A” in Table 1 indicates that the exposure unit A performs the scan in the region 520 four total times (i.e., exposure unit A is 100% responsible for region 520 for each pass). This is why the region 520 in each of the configurations 510-1 through 510-4 has the letter “A” written therein. As another example, the entry “3A+C” in Table 1 indicates that, in the region adjacent to the right edge of the region 520, the exposure unit A performs a scan three total times and the exposure unit C performs a scan one time. In this illustrative example, as shown in configurations 510-1 through 510-4, exposure unit A performs the scan in the region during the first pass, the third pass and the fourth pass, and exposure unit C performs the scan in the region during the second pass. That is, exposure unit A contributes to 75% of the scanning in the region, and exposure unit C contributes to 25% of the scanning in the region. However, this scan ordering is not limiting. For example, exposure unit C can perform the scan in the region during the first pass (as opposed to exposure unit A shown in configuration 510-1), while exposure unit A can perform the scan in the region during the second, third and fourth passes (as opposed to exposure unit C shown in configuration 510-2). As yet another example, the entry “A+B+C+D” in Table 1 indicates that, in the center region of configurations 510-1 through 510-4, each of the exposure units A through D performs one scan. In this illustrative example, exposure unit A performs the scan in the center region during the first pass, exposure unit C performs the scan in the center region during the second pass, exposure unit B performs the scan in the center region during the third pass, and exposure unit D performs the scan in the center region during the fourth pass. However, similar to above, this scan ordering is not limiting (as long as each of the exposure units A through D performs a single scan during a respective pass of the multi-pass process).

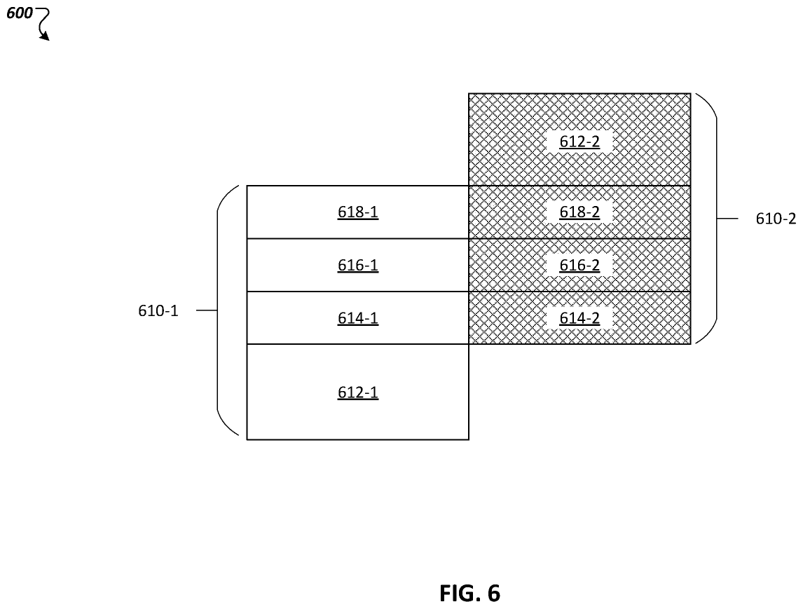

FIG. 6 is a diagram 600 illustrating another example of dose allocations of digital lithography exposure units in a one-bridge implementation, in accordance with some embodiments. The diagram 600 includes a dose allocation 610-1 corresponding to a first exposure unit and a dose allocation 610-2 corresponding to a second exposure unit. For the sake of illustration, the dose allocations 610-1 and 610-2 are shown as being separated or disjoint. However, in reality, the dose allocations 610-1 and 610-2 correspond to vertically aligned regions.

For example, the dose allocation 610-1 includes a dose value 612-1 for the first exposure unit at a first region, a dose value 614-1 for the first exposure unit at a second region, a dose value 616-1 for the first exposure unit at a third region, and a dose value 618-1 for the first exposure unit at a fourth region. The dose allocation 610-2 includes a dose value 612-2 for the second exposure unit at a fifth region, a dose value 614-2 for the second exposure unit at the second region, a dose value 616-2 for the second exposure unit at the third region, and a dose value 618-2 for the second exposure unit at the fourth region. In other words, the second region includes a mixing of the dose values 614-1 and 614-2, the third region includes a mixing of the dose values 616-1 and 616-2, and the fourth region includes a mixing of the dose values 618-1 and 618-2.

The sum of the mixed dose values should add up to 100% of the total dose for the corresponding region. For example, the dose values 612-1 and 612-2 can each be 100%, such that each exposure unit independently contributes 100% dosing for the first and fifth regions, respectively. The dose value 614-1 can illustratively be 75% and the dose value 614-2 can illustratively be 25%, and the contribution of each exposure unit adds up to 100% of the total dose of the second region. The dose values 616-1 and 616-2 can illustratively be 50%, and the contribution of each exposure unit adds up to 100% of the total dose of the third region. The dose value 618-1 can illustratively be 25% and the dose value 618-2 can illustratively be 75%, and the contribution of each exposure unit adds up to 100% of the total dose of the fourth region. However, these dose value examples are purely exemplary, and any suitable number of dose value mixtures N can be implemented in accordance with the embodiments described herein. The clipping layers corresponding to the first and second exposure units should be aligned to provide the overlap needed to achieve the dose value mixing.

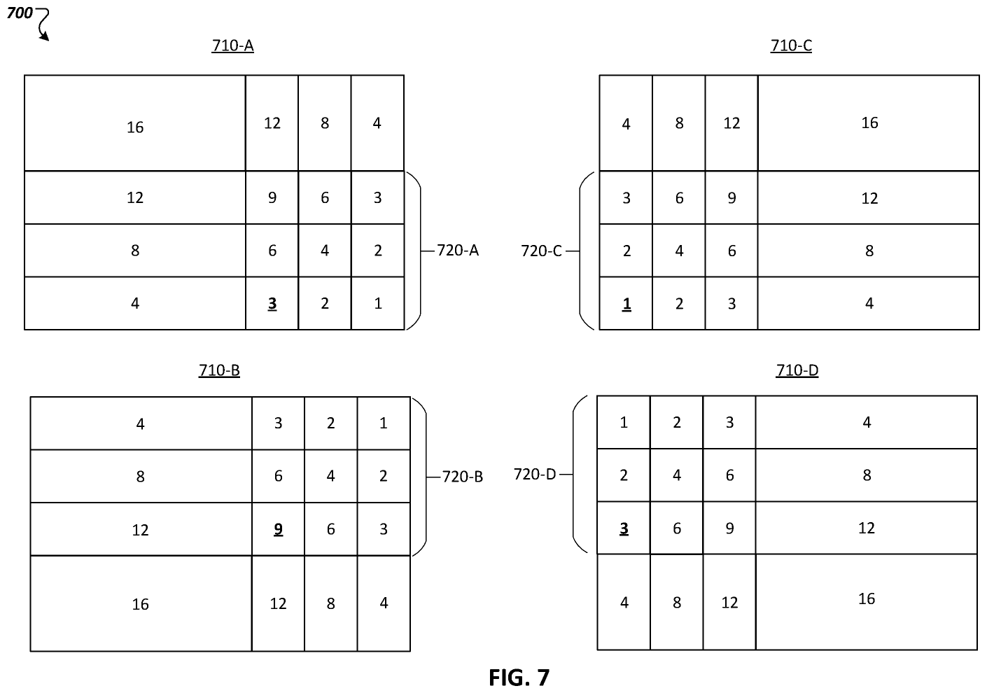

FIG. 7 is a diagram 700 illustrating example dose allocations of digital lithography exposure units in a two-bridge implementation, in accordance with some embodiments. The diagram 700 includes a dose allocation 710-A corresponding to an exposure unit A, a dose allocation 710-B corresponding to an exposure unit B, a dose allocation 710-C corresponding to an exposure unit C, and a dose allocation 710-D corresponding to an exposure unit D. In this example, exposure units A through D are located in adjacent scan regions, where the exposure units A and B are attached to a first bridge, and exposure units C and D are attached to a second bridge. For example, with reference to FIG. 1, exposure unit A can correspond to exposure unit 2, exposure unit B can correspond to exposure unit 1, exposure unit C can correspond to exposure unit 13, and exposure unit D can correspond to exposure unit 12.

The number in each box of the dose allocations 710-A through 710-D represents a relative dose for the corresponding exposure unit at each region, where the actual dose is divided by 16. For example, if the number in a box shown in dose allocation 710-A is “8,” then the actual dose contribution for exposure unit A for the corresponding region is 8/16=0.5 or 50%.

For the sake of illustration, the dose allocations 710-A through 710-D are shown as being separated. However, in reality, the dose allocations 710-A through 710-D overlap with respect to the 3×3 box regions 720-A through 720-D to form blending zones, such that the total dose from each of the exposure units A-D adds up to 100% (i.e., the relative doses add up to 16). For example, the total dose corresponding to the bolded and underlined values in each of the exposure unit dose allocations 710-A through 710-D can be represented by

$$\frac{3}{16} A + \frac{9}{16} B + \frac{1}{16} C + \frac{3}{16} D .$$

In this illustrative example, 9 dose values for each exposure unit A through D are achieved (corresponding to the relative doses 1, 2, 3, 4, 6, 8, 9, 12 and 16). However, these dose value examples are purely exemplary, and any suitable number of dose value mixtures N can be implemented in accordance with the embodiments described herein.

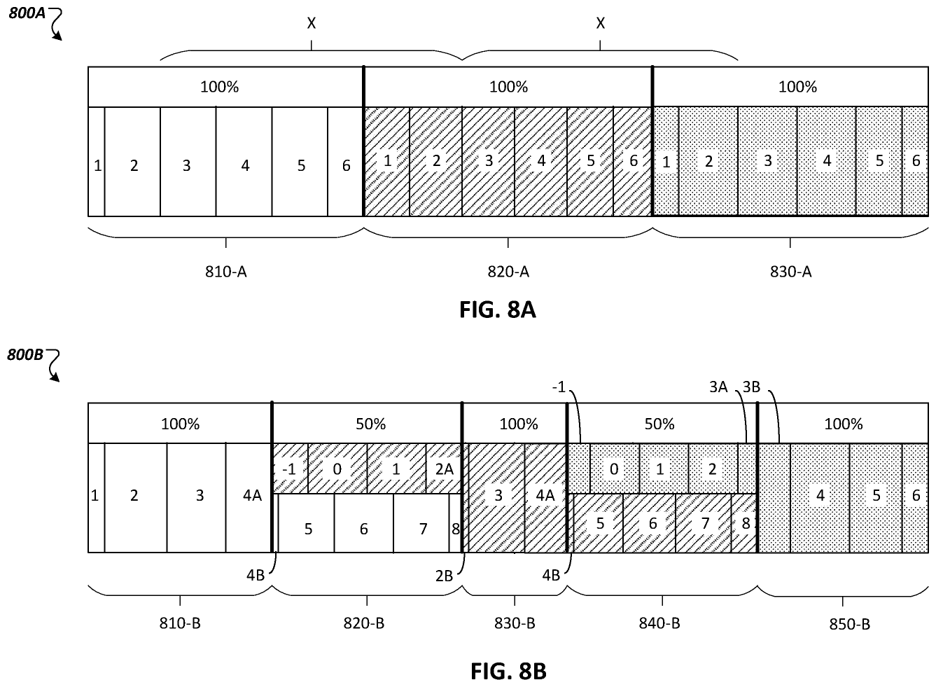

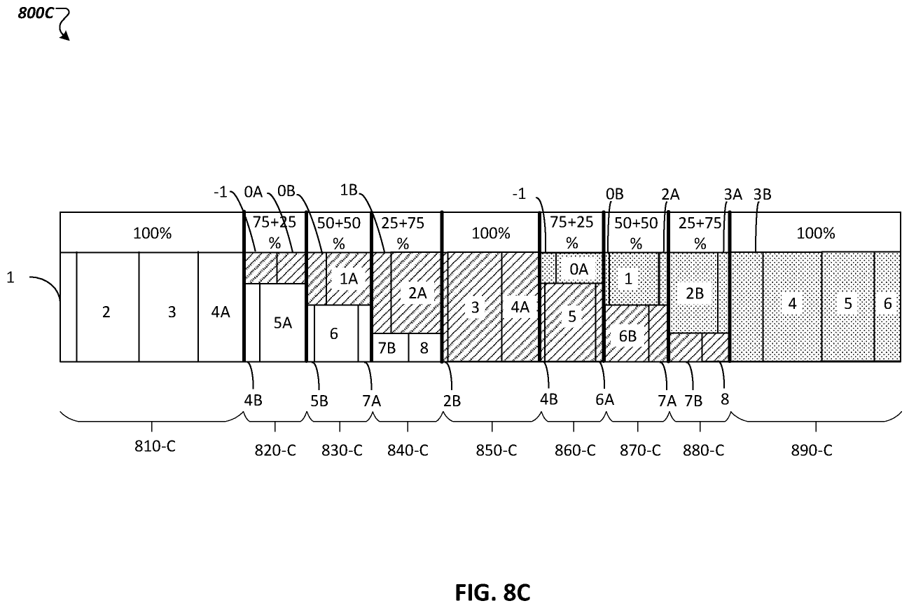

FIGS. 8A-8C are diagrams showing examples of digital lithography exposure unit dose allocations, in accordance with some embodiments. FIG. 8A depicts a diagram 800A with no exposure unit boundary smoothing or blending. For example, the diagram 800A shows a first scan region 810-A corresponding to a first exposure unit, a second scan region 820-A corresponding to a second exposure unit, and a third scan region 830-A corresponding to a third exposure unit. Each scan region 810-A through 830-A is associated with a number of scans each having a scan width. In this illustrative embodiment, six scans (1-6) are performed by each exposure unit within each scan region. However, the number of scans should not be considered limiting. A distance “X” is shown that denotes an exposure unit scan distance. Since there is no dose mixing, each exposure unit is responsible for 100% of the scanning within its corresponding region. Here, and as will be described below with reference to FIGS. 8B and 8C, scans performed by the first exposure unit are indicated by no fill, scans performed by the second exposure unit are indicated by stripes, and scans performed by the third exposure unit are indicated by stippling.

Scans 2-5 generally correspond to scans performed in the middle of the corresponding scan regions 810-A through 830-A, whereas scans 1 and 6 generally correspond to scans performed toward the edges or boundaries of the corresponding scan regions 810-A through 830-A. Scans 2-5 generally have the same or similar scan width. However, for scans 1 and 6, it can be observed that the scan width can be less than that of the scans 2-5. This can result from the way that the digital lithography system is assembled and calibrated. For example, each exposure unit can be installed to have a tolerance of about +/−1 millimeter (mm). Then, the system can be calibrated to determine a location of each exposure unit. The calibration can identify the scan width per scan in view of the how each exposure is disposed within the digital lithography system.

FIG. 8B depicts a diagram 800B with exposure unit boundary smoothing, in accordance with a first implementation. For example, the diagram 800B shows scan regions 810-B through 850-B. Each scan region 810-B through 850-B is associated with a number of scans each having a scan width. However, the number of scans and/or the scan widths should not be considered limiting.

As shown, a first exposure unit performs scans 1-4A in the scan region 810-B, where scan 4A corresponds to a first performance of scan 4 by the first exposure unit. Here, the first exposure unit performs 100% of the scanning within the scan region 810-B.

In scan region 820-B, the first exposure unit performs scans 4B-8, where scan 4B corresponds to a second performance of scan 4 by the first exposure unit. Additional scans 7 and 8 were used to extend the operation of the first exposure unit into the second exposure unit's original scan region (e.g., scan region 820-A of FIG. 8A). Moreover, a second exposure unit performs scans −1 through 2A, where scan 2A corresponds to a first performance of scan 2 by the second exposure unit. Additional scans −1 and 0 were used to extend the second exposure unit into the first exposure unit's original scan region (e.g., scan region 810-A of FIG. 8A). Here, each of the first and second exposure units scans about 50% of the scanning of the scan region 820-B.

In scan region 830-B, the second exposure unit performs scans 2B-4A, where scan 2B corresponds to a second performance of scan 2 by the second exposure unit and scan 4A corresponds to a first performance of scan 4 by the second exposure unit. Here, the second exposure unit scans 100% of the scan region 830-B.

In scan region 840-B, the second exposure unit performs scans 4B-8, where scan 4B corresponds to a second performance of scan 4 by the second exposure unit. Similar to the first exposure unit, additional scans 7 and 8 were used to extend the operation of the second exposure unit into the third exposure unit's original scan region (e.g., scan region 830-A of FIG. 8A). Moreover, the third exposure unit performs scans −1 through 3A, where scan 3A corresponds to a first performance of scan 3 by the third exposure unit. Additional scans −1 and 0 were used to extend the third exposure unit into the second exposure unit's original scan region (e.g., scan region 820-B of FIG. 8A). Here, each of the second and third exposure units scans about 50% of the scan region 840-B.

In scan region 850-B, the second exposure unit performs scans 3B-6, where scan 3B corresponds to a second performance of scan 3 by the third exposure unit. Here, the third exposure unit performs 100% of the scanning within the scan region 850-B. Accordingly, the scan regions 820-B and 840-B correspond to overlapping ranges where adjacent pairs of exposure units are scan about 50% of the scan region.

Scan 4 performed by the first exposure unit, scans 2 and 4 performed by the second exposure unit, and scan 3 performed by the third exposure unit correspond to scans that cross into the dose mixing boundary between scan regions. Thus, these scans are doubled or performed twice in order to perform dose mixing in accordance with FIG. 8B. For example, with respect to the first exposure unit, the stage can stay at the same Y-position during the printing of its corresponding scan 4. The first exposure unit can use 100% dose to print 4A in one scan, and 50% dose to print 4B in another scan.

FIG. 8C depicts a diagram 800C with exposure unit boundary smoothing, in accordance with a second implementation. For example, the diagram 800B shows scan regions 810-C through 890-C. Each scan region 810-C through 890-C is associated with a number of scans each having a scan width. However, the number of scans and/or the scan widths should not be considered limiting. A first exposure unit performs 100% of the scanning within the scan region 810-C, a second exposure unit performs 100% of the scanning within the scan region 850-C, and a third exposure unit performs 100% of the scanning with the scan region 890-C.

As shown, a first exposure unit performs scans 1-4A in the scan region 810-C, where scan 4A corresponds to a first portion of scan 4 performed by the first exposure unit. Here, the first exposure unit scan 100% of the scan region 810-C.

In scan region 820-C, the first exposure unit performs scans 4B and 5A, where scan 4B corresponds to a second portion of scan 4 performed by the first exposure unit and scan 5A corresponds to a first portion of scan 5 performed by the first exposure unit. Moreover, a second exposure unit performs scans −1 and 0A, where scan 0A corresponds to a first portion of scan 0 performed by the second exposure unit. Additional scans −1 and 0 were used to extend the second exposure unit into the first exposure unit's original scan region (e.g., scan region 810-A of FIG. 8A). Here, the first exposure unit scans about 75% of the scan region 820-C and the second exposure unit scans about 25% of the scan region 820-C.

In scan region 830-C, the first exposure unit performs scans 5B-7A, where scan 6B corresponds to a second portion of scan 6 performed by the first exposure unit and scan 7A corresponds to a first portion of scan 7 performed by the first exposure unit. Moreover, the second exposure unit performs scans 0B and 1A, where scan 0B corresponds to a second portion of scan 0 performed by the second exposure unit and scan 1A corresponds to a first portion of scan 1 performed by the second exposure unit. Here, each of the first and second exposure units scans about 50% of the scan region 830-C.

In scan region 840-C, the first exposure unit performs scans 7B and 8, where scan 7B corresponds to a second portion of scan 7 performed by the first exposure unit. Moreover, the second exposure unit performs scans 1B and 2A, where scan 1B corresponds to a second portion of scan 1 performed by the second exposure unit and scan 2A corresponds to a first portion of scan 2 performed by the second exposure unit. Here, the first exposure unit scans about 25% of the scan region 840-C and the second exposure unit scans about 75% of the scan region 840-C.

With respect to scan regions 820-C through 840-C, additional scans 7 and 8 were used to extend the first exposure unit into the second exposure unit's original scan region (e.g., scan region 820-A of FIG. 8A). Moreover, additional scans −1 and 0 were used to extend the second exposure unit into the first exposure unit's original scan region (e.g., scan region 810-A of FIG. 8A).

In scan region 850-C, the second exposure unit performs scans 2B-4A, where scan 2B corresponds to a second portion of scan 2 performed by the second exposure unit and scan 4A corresponds to a first portion of scan 4 performed by the second exposure unit. Here, the second exposure unit scans 100% of the scan region 850-C.

In scan region 860-C, the second exposure unit performs scans 4B-6A, where scan 4B corresponds to a second portion of scan 4 performed by the second exposure unit and scan 6A corresponds to a first portion of scan 6 performed by the second exposure unit. Moreover, the third exposure unit performs scans −1 and 0A, where scan 0A corresponds to a first portion of scan 0 performed by the third exposure unit. Here, the second exposure unit scans about 75% of the scan region 860-C and the third exposure unit scans about 25% of the scan region 860-C.

In scan region 870-C, the second exposure unit performs scans 6B and 7A, where scan 6B corresponds to a second portion of scan 6 performed by the second exposure unit and scan 7A corresponds to a first portion of scan 7 performed by the second exposure unit. Moreover, the third exposure unit performs scans 0B through 2A, where scan 0B corresponds to a second portion of scan 0 performed by the third exposure unit and scan 2A corresponds to a first portion of scan 2 performed by the third exposure unit. Here, each of the second and third exposure units scans about 50% of the scan region 870-C.

In scan region 880-C, the second exposure unit performs scans 7B and 8, where scan 7B corresponds to a second portion of scan 7 performed by the second exposure unit. Moreover, the third exposure unit performs scans 2B through 3A, where scan 2B corresponds to a second portion of scan 2 performed by the third exposure unit and scan 3A corresponds to a first portion of scan 3 performed by the third exposure unit. Here, the second exposure unit scans about 25% of the scan region 880-C and the third exposure unit scans about 75% of the scan region 880-C.

With respect to scan regions 860-C through 880-C, additional scans 7 and 8 were used to extend the second exposure unit into the third exposure unit's original scan region (e.g., scan region 830-A of FIG. 8A). Moreover, additional scans −1 and 0 were used to extend the third exposure unit into the second exposure unit's original scan region (e.g., scan region 820-A of FIG. 8A).

In scan region 890-C, the third exposure unit performs scans 3B through 6, where scan 3B corresponds to a second portion of scan 3 performed by the third exposure unit. Here, the third exposure unit performs 100% of the scanning within the scan region 890-C.

Scans 4, 5 and 7 performed by the first exposure unit, scans 0, 1, 2, 4, 6 and 7 performed by the second exposure unit, and scans 0, 2, and 3 performed by the third exposure unit correspond to scans that encroach into dose mixing boundary between scan regions. Thus, these scans are doubled or performed twice about the corresponding dose mixing boundaries in order to perform dose mixing in accordance with FIG. 8C.

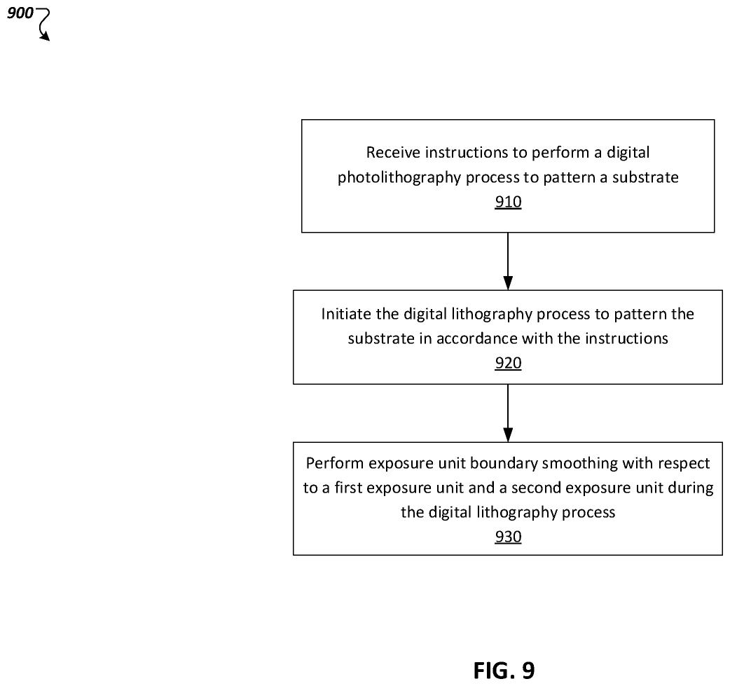

FIG. 9 depicts a flow diagram of a method 900 for implementing digital lithography exposure unit boundary smoothing, in accordance with some embodiments. The method may be performed by processing logic that may comprise hardware (circuitry, dedicated logic, etc.), computer readable instructions (run on a general purpose computer system or a dedicated machine), or a combination of both. In an illustrative example, method 900 may be performed by a processing device of a digital lithography system. It should be noted that blocks depicted in FIG. 9 could be performed simultaneously or in a different order than that depicted.

At block 910, the processing logic receives instructions to perform a digital photolithography process to pattern a substrate, and at block 920, the processing logic initiates the digital lithography process to pattern the substrate in accordance with instructions. The substrate can be disposed on the stage, and the stage can move in X-Y directions underneath digital lithography exposure units (“exposure units”) in accordance with the instructions. For example, the instructions can be executed to implement exposure unit boundary smoothing (e.g., exposure unit boundary shifting and/or dose mixing).

At block 930, the processing logic performs exposure unit boundary smoothing with respect to a first exposure unit and a second exposure unit during the digital lithography process. The first exposure unit corresponds to a first scan region and the second exposure unit corresponds to a second scan region adjacent to the first scan region. Implementing exposure unit boundary smoothing can include having the first exposure unit extend into the second scan region and having the second exposure unit extend into the first scan region.

In some embodiments, the digital lithography process includes multiple pass process including a plurality of passes, and implementing the exposure unit boundary smoothing includes performing exposure unit boundary shifting as part of the multiple pass process. For example, exposure unit boundary shifting can be implemented in a one-bridge implementation. Here, the first and second exposure units are attached to a same bridge above the stage of the digital photolithography system, and performing the exposure unit boundary shifting includes performing a first pass of the multiple pass process, in response to performing the first pass, performing a vertical boundary shift, and in response to performing the vertical boundary shift, performing a second pass of the multiple pass process. Further details regarding the one-bridge implementation of exposure unit boundary shifting are described above with reference to FIG. 4.

As another example, exposure unit boundary shifting can be implemented in a two-bridge implementation. Here, the first and second exposure units are attached to a first bridge, and the plurality of exposure units further include a third exposure unit associated with a third scan region and a fourth exposure unit associated with a fourth scan region adjacent to the third scan region, such that the third and fourth exposure units are attached to a second bridge adjacent to the first bridge. Performing the exposure unit boundary shifting would then include performing the plurality of passes in accordance with a blending specification indicating a total number of doses to be performed by the first, second, third and fourth exposure units in respective regions during the multiple pass process. Further details regarding the two-bridge implementation of exposure unit boundary shifting are described above with reference to FIG. 5.

In some embodiments, implementing the exposure unit boundary smoothing includes performing dose mixing about a boundary between the first scan region and the second scan region. For example, dose mixing can be implemented in a one-bridge implementation. Here, the first and second exposure units are attached to a same bridge above the stage of the digital photolithography system, and performing the dose mixing includes having the first exposure unit contribute a first percentage of a total dose to a blended region and the second exposure unit contribute a second percentage of the total dose to the blended region, such that a sum of the first and second percentages equals 100%. Further details regarding the one-bridge implementation of exposure unit boundary shifting are described above with reference to FIG. 6.

As another example, dose mixing can be implemented in a two-bridge implementation. Here, the first and second exposure units are attached to a first bridge, and the plurality of exposure units further include a third exposure unit associated with a third scan region and a fourth exposure unit associated with a fourth scan region adjacent to the third scan region, such that the third and fourth exposure units are attached to a second bridge adjacent to the first bridge. Performing the dose mixing would then include having the first exposure unit contribute a first percentage of a total dose to a blended region, the second exposure unit contribute a second percentage of the total dose to the blended region, the third exposure unit contribute a third percentage of the total dose to the blended region, and the fourth exposure unit contribute a fourth percentage of the total dose to the blended region, such that a sum of the first, second, third and fourth percentages equals 100%. Further details regarding the two-bridge implementation of dose mixing are described above with reference to FIG. 7.

Further details regarding the method 900, including exposure unit boundary shifting and dose mixing, are described above with reference to FIGS. 1-8.

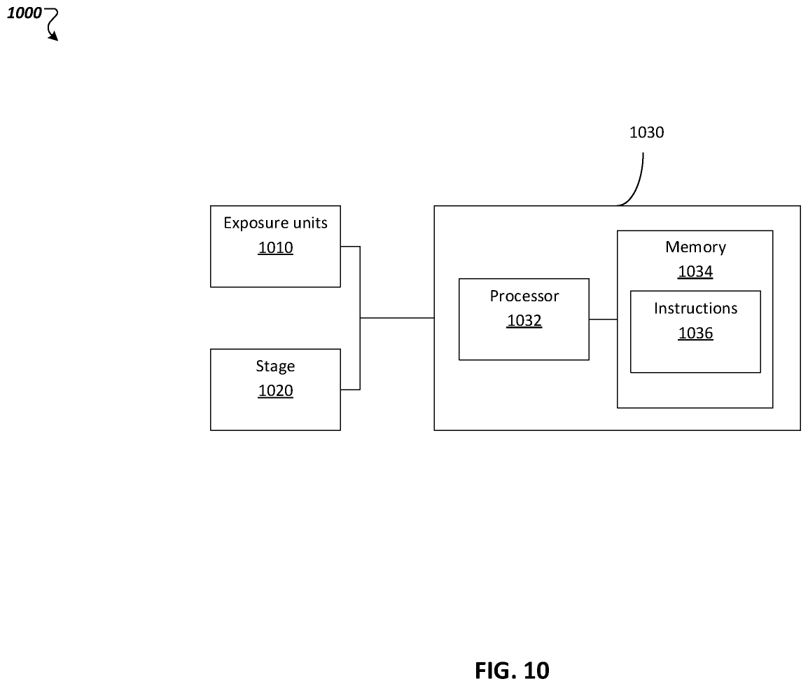

FIG. 10 is a block diagram illustrating a digital lithography system (“system”) 900, in accordance with some embodiments. As shown, the system 1000 includes digital lithography exposure units (“exposure units”) 1010, a stage 1020, and a processing device 1030. The processing device 1030 includes a processor 1032 operatively coupled to a memory 1034. The memory can maintain instructions 1036 for performing digital lithography within the system 1000. For example, the instructions 1026 can include instructions for controlling the movement of the stage 1020 and/or exposure units 1010. When executed, the instructions can implement the methods for performing exposure unit boundary smoothing described herein above.

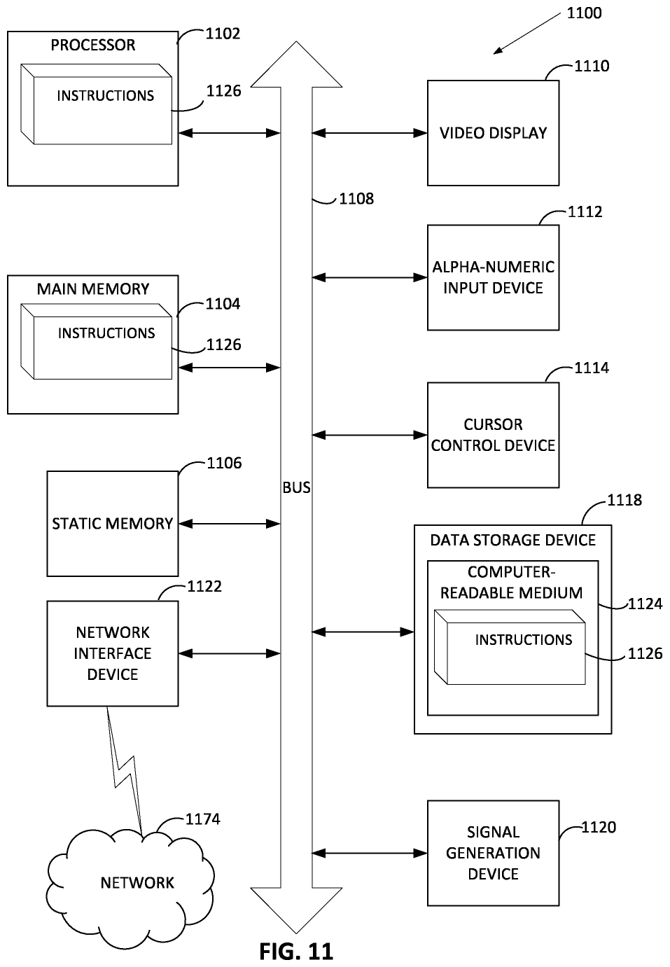

FIG. 11 is a block diagram illustrating a computer system 1100, according to certain embodiments. In some embodiments, computer system 1100 is connected (e.g., via a network, such as a Local Area Network (LAN), an intranet, an extranet, or the Internet) to other computer systems. In some embodiments, computer system 1100 operates in the capacity of a server or a client computer in a client-server environment, or as a peer computer in a peer-to-peer or distributed network environment. In some embodiments, computer system 1100 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 1100 includes a processing device 1102, a volatile memory 1104 (e.g., Random Access Memory (RAM)), a non-volatile memory 1106 (e.g., Read-Only Memory (ROM) or Electrically-Erasable Programmable ROM (EEPROM)), and a data storage device 1116, which communicate with each other via a bus 1108.

In some embodiments, processing device 1102 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 1100 further includes a network interface device 1122 (e.g., coupled to network 1174). In some embodiments, computer system 1100 also includes a video display unit 1110 (e.g., an LCD), an alphanumeric input device 1112 (e.g., a keyboard), a cursor control device 1114 (e.g., a mouse), and a signal generation device 1120.

In some implementations, data storage device 1116 includes a non-transitory computer-readable storage medium 1124 on which store instructions 1126 encoding any one or more of the methods or functions described herein. For example, the instructions 1126 can include instructions for controlling the movement of the stage and/or digital lithography exposure units (“exposure units”) of a digital lithography system, which, when executed, can implement the methods for performing exposure unit boundary smoothing described herein.

In some embodiments, instructions 1126 also reside, completely or partially, within volatile memory 1104 and/or within processing device 1102 during execution thereof by computer system 1100, hence, in some embodiments, volatile memory 1104 and processing device 1102 also constitute machine-readable storage media.

While computer-readable storage medium 1124 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as ASICS, FPGAs, DSPs or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “training,” “identifying,” “further training,” “re-training,” “causing,” “receiving,” “providing,” “obtaining,” “optimizing,” “determining,” “updating,” “initializing,” “generating,” “adding,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

1. A digital lithography system comprising:
a plurality of scan regions comprising a first scan region and a second scan region adjacent to the first scan region;
a plurality of exposure units located above the plurality of scan regions, the plurality of exposure units comprising a first exposure unit associated with the first scan region and a second exposure unit associated with the second scan region;
a memory; and
at least one processing device, operatively coupled to the memory, to perform operations comprising:
initiating a digital lithography process to pattern a substrate disposed on a stage in accordance with instructions; and
performing exposure unit boundary smoothing with respect to the first and second exposure units during the digital lithography process.

2. The digital lithography system of claim 1, wherein the digital lithography process is a multiple pass process including a plurality of passes, and wherein implementing the exposure unit boundary smoothing comprises performing exposure unit boundary shifting as part of the multiple pass process.

3. The digital lithography system of claim 2, wherein the first and second exposure units are attached to a same bridge, and wherein performing the exposure unit boundary shifting comprises:
performing a first pass of the multiple pass process;
in response to performing the first pass, performing a vertical boundary shift; and
in response to performing the vertical boundary shift, performing a second pass of the multiple pass process.

4. The digital lithography system of claim 2, wherein:
the first exposure unit and the second exposure unit are attached to a first bridge;
the plurality of scan regions further comprises a third scan region and a fourth scan region adjacent to the third scan region;
the plurality of exposure units further comprises a third exposure unit associated with the third scan region and a fourth exposure unit associated with the fourth scan region, the third and fourth exposure units being attached to a second bridge adjacent to the first bridge; and
performing the exposure unit boundary shifting comprises performing the plurality of passes in accordance with a blending specification indicating a total number of doses to be performed by the first, second, third and fourth exposure units in respective regions during the multiple pass process.

5. The digital lithography system of claim 1, wherein implementing the exposure unit boundary smoothing comprises performing dose mixing about a boundary between the first scan region and the second scan region.

6. The digital lithography system of claim 5, wherein the first exposure unit and the second exposure unit are attached to a same bridge, and wherein performing the dose mixing comprises having the first exposure unit contribute a first percentage of a total dose to a blended region and the second exposure unit contribute a second percentage of the total dose to the blended region, such that a sum of the first percentage and the second percentage equals 100%.

7. The digital lithography system of claim 5, wherein:
the first exposure unit and the second exposure unit are attached to a first bridge;
the plurality of scan regions further comprises a third scan region and a fourth scan region adjacent to the third scan region;
the plurality of exposure units further comprises a third exposure unit associated with the third scan region and a fourth exposure unit associated with the fourth scan region, the third and fourth exposure units being attached to a second bridge adjacent to the first bridge; and
performing the dose mixing comprises having the first exposure unit contribute a first percentage of a total dose to a blended region, the second exposure unit contribute a second percentage of the total dose to the blended region, the third exposure unit contribute a third percentage of the total dose to the blended region, and the fourth exposure unit contribute a fourth percentage of the total dose to the blended region, such that a sum of the first, second, third and fourth percentages equals 100%.

8. A system comprising:
a memory; and
at least one processing device, operatively coupled to the memory, to perform operations comprising:
initiating a digital lithography process to pattern a substrate in accordance with instructions; and
performing exposure unit boundary smoothing with respect to a first exposure unit of a plurality of exposure units and a second exposure unit of the plurality of exposure units during the digital lithography process, wherein the first exposure unit corresponds to a first scan region of a plurality of scan regions and the second exposure unit corresponds to a second scan region of the plurality of scan regions, adjacent to the first scan region.

9. The system of claim 8, wherein the digital lithography process is a multiple pass process including a plurality of passes, and wherein implementing the exposure unit boundary smoothing comprises performing exposure unit boundary shifting as part of the multiple pass process.

10. The system of claim 9, wherein the first exposure unit and the second exposure unit are attached to a same bridge, and wherein performing the exposure unit boundary shifting comprises:
performing a first pass of the multiple pass process;
in response to performing the first pass, performing a vertical boundary shift; and
in response to performing the vertical boundary shift, performing a second pass of the multiple pass process.

11. The system of claim 9, wherein:
the first exposure unit and the second exposure unit are attached to a first bridge;
the plurality of exposure units further comprises a third exposure unit associated with a third scan region and a fourth exposure unit associated with a fourth scan region adjacent to the third scan region, the third and fourth exposure units being attached to a second bridge adjacent to the first bridge; and
performing the exposure unit boundary shifting comprises performing the plurality of passes in accordance with a blending specification indicating a total number of doses to be performed by the first, second, third and fourth exposure units in respective regions during the multiple pass process.

12. The system of claim 8, wherein:
implementing the exposure unit boundary smoothing comprises performing dose mixing about a boundary between the first scan region and the second scan region;
the first and second exposure units are attached to a same bridge; and
performing the dose mixing comprises having the first exposure unit contribute a first percentage of a total dose to a blended region and the second exposure unit contribute a second percentage of the total dose to the blended region, such that a sum of the first percentage and the second percentage equals 100%

13. The system of claim 8, wherein:
implementing the exposure unit boundary smoothing comprises performing dose mixing about a boundary between the first scan region and the second scan region;
the first exposure unit and the second exposure unit are attached to a first bridge;
the plurality of scan regions further comprises a third scan region and a fourth scan region adjacent to the first scan region;
the plurality of exposure units further comprises a third exposure unit associated with the third scan region and a fourth exposure unit associated with the fourth scan region, the third and fourth exposure units being attached to a second bridge adjacent to the first bridge; and
performing the dose mixing comprises having the first exposure unit contribute a first percentage of a total dose to a blended region, the second exposure unit contribute a second percentage of the total dose to the blended region, the third exposure unit contribute a third percentage of the total dose to the blended region, and the fourth exposure unit contribute a fourth percentage of the total dose to the blended region, such that a sum of the first, second, third and fourth percentages equals 100%.

14. A method comprising:
initiating, by a processing device, a digital lithography process to pattern a substrate in accordance with instructions; and
performing, by the processing device, exposure unit boundary smoothing with respect to a first exposure unit of a plurality of exposure units and a second exposure unit of the plurality of exposure units during the digital lithography process, wherein the first exposure unit corresponds to a first scan region of a plurality of scan regions and the second exposure unit corresponds to a second scan region of the plurality of scan regions, adjacent to the first scan region.

15. The method of claim 14, wherein the digital lithography process is a multiple pass process including a plurality of passes, and wherein implementing the exposure unit boundary smoothing comprises performing exposure unit boundary shifting as part of the multiple pass process.

16. The method of claim 15, wherein the first exposure unit and the second exposure unit are attached to a same bridge, and wherein performing the exposure unit boundary shifting comprises:
performing a first pass of the multiple pass process;
in response to performing the first pass, performing a vertical boundary shift; and
in response to performing the vertical boundary shift, performing a second pass of the multiple pass process.

17. (canceled)

18. The method of claim 14, wherein implementing the exposure unit boundary smoothing comprises performing dose mixing about a boundary between the first scan region and the second scan region.

19. The method of claim 18, wherein the first exposure unit and the second exposure unit are attached to a same bridge, and wherein performing the dose mixing comprises having the first exposure unit contribute a first percentage of a total dose to a blended region and the second exposure unit contribute a second percentage of the total dose to the blended region, such that a sum of the first percentage and the second percentage equals 100%.

20. The method of claim 18, wherein:
the first exposure unit and the second exposure unit are attached to a first bridge;
the plurality of scan regions further comprises a third scan region and a fourth scan region adjacent to the first scan region;
the plurality of exposure units further comprises a third exposure unit associated with the third scan region and a fourth exposure unit associated with the fourth scan region, the third and fourth exposure units being attached to a second bridge adjacent to the first bridge; and
performing the dose mixing comprises having the first exposure unit contribute a first percentage of a total dose to a blended region, the second exposure unit contribute a second percentage of the total dose to the blended region, the third exposure unit contribute a third percentage of the total dose to the blended region, and the fourth exposure unit contribute a fourth percentage of the total dose to the blended region, such that a sum of the first, second, third and fourth percentages equals 100%.

21. The system of claim 8, wherein implementing the exposure unit boundary smoothing comprises performing dose mixing about a boundary between the first scan region and the second scan region.
